(19) United States
(12) Patent Application Publication
(10) Pub. No.: US 2005/0139879 A1
(43) Pub. Date: Jun. 30, 2005

(54) Ion implanting conductive electrodes of polymer memories

(76) Inventors: Daniel C. Diana, Portland, OR (US); Hitesh Windlass, Hillsboro, OR (US); William C. Hicks, Gaston, OR (US); Timothy Lanfri, Beaverton, OR (US); Michael A. Deangelis, Portland, OR (US); Ebrahim Andideh, Portland, OR (US)

Correspondence Address: TROP PRUNER & HU, PC, 8554 KATY FREEWAY, SUITE 100, HOUSTON, TX, 77024, US

(21) Appl. No.: 10/746,073

(22) Filed: Dec. 24, 2003

(51) Int. Cl. H01L 21/00; H01L 29/76

(52) U.S. Cl. 257/295; 438/3

(57) ABSTRACT

An electrode layer for a polymer memory may be implanted to increase the number of defects in the material. As a result, that same material may be utilized for the upper and lower electrodes. In particular, defects may be introduced into a TiOₓ layer within the electrode to match the work functions of the upper and lower electrodes.

### BACKGROUND

This invention relates generally to polymer memories.

A ferroelectric polymer memory may be used to store data. The data may be stored in layers within the memory. The higher the number of layers, the higher the capacity of the memory. Each of the polymer layers includes polymer chains with dipole moments. Data may be stored by changing the polarization of the polymer between metal lines. No transistors may be needed for storage.

Ferroelectric polymer memories are non-volatile memories with sufficiently fast read and write speeds. For example, microsecond initial reads may be possible with write speeds comparable to those with flash memories.

Conventionally, polymer memories are formed by a layer of polymer between upper and lower parallel electrodes. Thus, successive, vertically spaced sets of horizontal metal lines may be utilized to define a polymer memory cell between upper and lower lines.

Polymer memories are subject to a disturb problem. A disturb is polarization lost on a cell due to the application of a voltage less than that required to switch the cell. To overcome this problem, an electrode stack that includes different materials for the upper and lower electrodes has been suggested. For example, a TiOₓ top electrode may be used with a bottom electrode made of a different material, such as titanium nitride or tantalum nitride. Although this asymmetric electrode approach has shown good results, the difference in work functions between titanium nitride and TiOₓ electrodes results in differences in charge injection capability into the ferroelectric polymer.

Thus, there is a need for alternate ways to overcome the disturb problem in polymer memories.

### BRIEF DESCRIPTION OF THE DRAWINGS

FIG. 1 is an enlarged, cross-sectional view of one embodiment of the present invention at an early stage of manufacture;

FIG. 2 is an enlarged, cross-sectional view corresponding to FIG. 1 at a subsequent stage of manufacture in accordance with one embodiment of the present invention;

FIG. 3 is a top plan view of the embodiment shown in FIG. 2;

FIG. 4 is an enlarged, cross-sectional view of the embodiment shown in FIG. 3 after further processing in accordance with one embodiment of the present invention;

FIG. 5 is an enlarged, cross-sectional view of the embodiment shown in FIG. 4 after further processing in accordance with one embodiment of the present invention;

FIG. 6 is an enlarged, top plan view of the embodiment shown in FIG. 5 in accordance with one embodiment of the present invention; and

FIG. 7 is a depiction of a system in accordance with one embodiment of the present invention.

### DETAILED DESCRIPTION

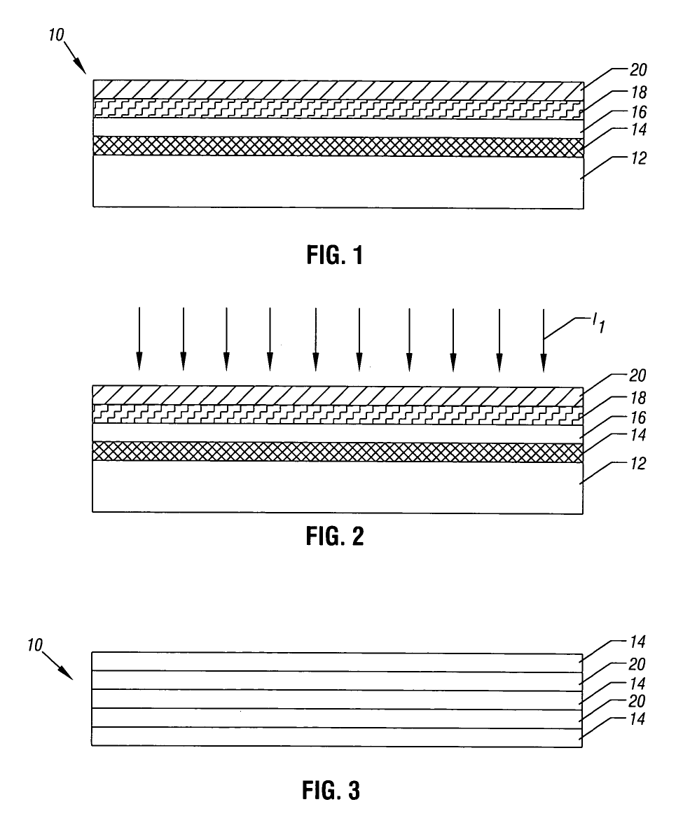

Referring to FIG. 1, a polymer memory structure 10 may include a silicon substrate 12 covered by an insulator 14. The insulator 14, in one embodiment, may be silicon dioxide or polyimide. A lower electrode, including the layers 20, 18, and 16, may be formed over the insulator 14. In one embodiment, the layer 16 may be aluminum, the layer 18 may be titanium, and the layer 20 may be TiOₓ, where x is between 1 and 2. The TiOₓ layer may be evaporated in one embodiment of the present invention.

Referring to FIG. 2, the TiOₓ layer 20 may be subjected to an ion implantation indicated as I₁. The ion implantation species may be germanium in one embodiment. The dose and energy may be optimized to maximize the electrically active defect sites in some embodiments of the present invention. In some cases the energy may be from about 5 to 15 keV with a dose in the range of 1E15 to 1E16 atoms per square centimeter. In general, the implantation conditions may be sufficient to make the TiOₓ layer 20 amorphous, in one example.

The use of ion implantation enhances the performance of TiOₓ as the bottom and top electrodes of a polymer memory. The implantation provides the ability modify the work function of the electrode interfaces. It is believed that the modification occurs by introducing vacancies and interstitial defects into the TiOₓ layer 20, that enhance the conductivity by providing sites where electrons and holes can “hop” through the material.

Referring to FIG. 3, the intermediate structure may include a lower electrode made up of layers 16, 18, and 20 patterned into strips through the use of suitable lithography, etch and cleans processes. As a result, between the electrode strips indicated by the presence of the upper TiOₓ layer 20, the insulator 14 is exposed. Thus, a series of parallel strips of lower electrodes are spaced from one another. Many more strips of electrodes may be used in some embodiments.

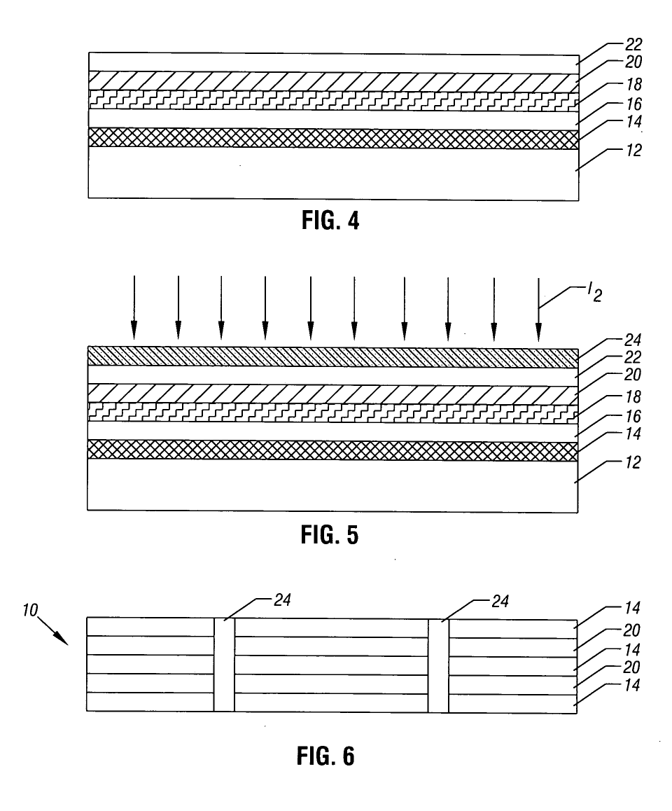

Referring to FIG. 4, a polymer material 22 may then be deposited over the entire structure, including the lower electrode and the exposed insulator 14. In one embodiment of the present invention, the polymer material 22 may be spin cast from a solution of a copolymer of vinylidene fluoride (VDF) and trifluoroethylene (TrFE).

Other ferroelectric or non-ferroelectric polymer materials may be utilized as the material 22 as well, including polyethylene fluoride, copolymers, and combinations thereof, polyacrylonitriles copolymers thereof, and combinations thereof, and polyamides, copolymers thereof, and combinations thereof.

In some embodiments, the lower TiOₓ layer 20 is implanted to enable both upper and lower electrodes to use TiOₓ In one embodiment, the lower TiOₓ layer 20 is the only implanted layer.

Referring to FIG. 5, thereafter, a second TiOₓ layer 24 may be deposited, again using evaporation in one embodiment of the present invention. The layer 24 may then be subjected to a second, optional, ion implantation step. In the case of the implantation I₂, it is desirable in some embodiments to maximize the number of defects without contaminating (i.e. implanting species into) the polymer layer 22. This may be done by adjusting the species, dose, and energy. For example, energies of less than 5 keV may be used with a dose in the range of 1E15 to 1E16 atoms per square centimeter and a high atomic mass species such as germanium. The layer 24 may be 200 Angstroms thick in one embodiment.

As shown in FIG. 6, the resulting structure has a second electrode 24 arranged generally transversely to the lower electrode represented by its upper TiOₓ layer 20. As shown in FIG. 5, the second electrode 24, like the lower electrode, may be formed of a stack of layers, including titanium oxide, titanium, and aluminum.

The upper electrode 24 may be patterned, etched, and photoresist cleaned using any suitable patterning and cleaning processes. Thereafter, additional layers of polymer material and lower and upper electrodes may be stacked on top of the structure shown in FIG. 6.

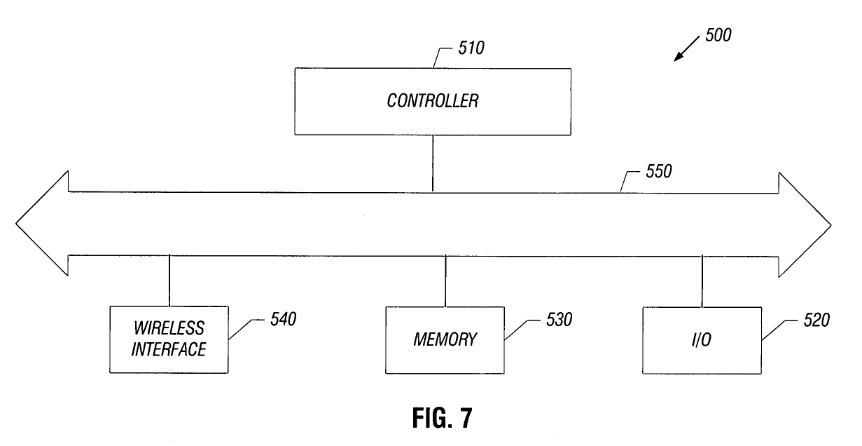

Turning to FIG. 7, a portion of a system 500 in accordance with an embodiment of the present invention is described. The system 500 may be used in wireless devices such as, for example, a personal digital assistant (PDA), a laptop or portable computer with wireless capability, a web tablet, a wireless telephone, a pager, an instant messaging device, a digital music player, a digital camera, or other devices that may be adapted to transmit and/or receive information wirelessly. The system 500 may be used in any of the following systems: a wireless local area network (WLAN) system, a wireless personal area network (WPAN) system, or a cellular network, although the scope of the present invention is not limited to these wireless and/or portable systems or to wireless applications in general.

The system 500 may include a controller 510, an input/output (I/O) device 520 (e.g. a keypad, display), a memory 530, and a wireless interface 540 coupled to each other via a bus 550. It should be noted that the scope of the present invention is not limited to embodiments having any or all of these components.

The controller 510 may comprise, for example, one or more microprocessors, digital signal processors, micro-controllers, or the like. Memory 530 may be used to store messages transmitted to or by system 500. Memory 530 may also optionally be used to store instructions that are executed by the device 510 during the operation of system 500, and may be used to store user data. Memory 530 may be provided by one or more different types of memory. For example, memory 530 may comprise a volatile memory (any type of random access memory), a non-volatile memory such as a flash memory, a static random access memory and/or a polymer memory of the type illustrated in FIG. 6.

The I/O device 520 may be used to generate a message. The system 500 may use the wireless interface 540 to transmit and receive messages to and from a wireless communication network with a radio frequency (RF) signal. Examples of the wireless interface 540 may include a wireless transceiver or an antenna, such as a dipole antenna, although the scope of the present invention is not limited in this respect.

While the present invention has been described with respect to a limited number of embodiments, those skilled in the art will appreciate numerous modifications and variations therefrom. It is intended that the appended claims cover all such modifications and variations as fall within the true spirit and scope of this present invention.

1. A method comprising:
implanting an electrode of a polymer memory.

2. The method of claim 1 including depositing TiOₓ to form said electrode.

3. The method of claim 1 including depositing a material to form a lower electrode of a polymer memory and implanting said lower electrode.

4. The method of claim 1 including forming an amorphous layer in said electrode.

5. The method of claim 3 including covering the lower electrode with polymer.

6. The method of claim 5 including forming an upper electrode over said polymer.

7. The method of claim 6 including forming the upper and lower electrodes of the same material.

8. The method of claim 6 including forming a TiOₓ layer as at least part of said upper and lower electrodes.

9. A polymer memory comprising:
an upper electrode including a TiOₓ layer;
a lower electrode including a TiOₓ layer; and
a polymer between said electrodes.

10. The memory of claim 9 wherein at least one of said TiOₓ layers is amorphous.

11. The memory of claim 9 wherein at least one of said TiOₓ layers is ion implanted.

12. The memory of claim 9 wherein said polymer is a ferroelectric polymer.

13. The memory of claim 9 wherein said polymer is a copolymer of vinylidene fluoride.

14. A system comprising:
a controller;
a polymer memory coupled to said controller including an upper electrode including a TiOₓ layer, a lower electrode including a TiOₓ layer, and a polymer between said electrodes; and
a wireless interface.

15. The system of claim 14 wherein at least one of said TiOₓ layers is amorphous.

16. The system of claim 14 wherein at least one of said TiOₓ layers is ion implanted.

17. The system of claim 14 wherein said polymer is a ferroelectric polymer.

18. The system of claim 14 wherein said wireless interface includes a dipole antenna.

19. A semiconductor structure comprising:
a first electrode having an amorphous layer; and
a polymer material on one side of said first electrode.

20. The structure of claim 19 wherein said first amorphous electrode layer includes TiOₓ.

21. The structure of claim 19 including a second electrode on said polymer material, said polymer material having opposed sides, said second electrode being on an opposite side of said polymer material from said first electrode.

22. The structure of claim 19 wherein said polymer material is a ferroelectric polymer.

23. The structure of claim 19 wherein said polymer material is a copolymer of vinylidene fluoride.

24. A method comprising:
forming an amorphous layer in an electrode of a polymer memory.

25. The method of claim 24 including depositing TiOₓ to form said electrode.

26. The method of claim 24 including depositing material to form a lower electrode of the polymer memory and implanting said lower electrode.

27. The method of claim 26 including covering said lower electrode with polymer.

28. The method of claim 27 including forming an upper electrode over said polymer.

29. The method of claim 28 including forming the upper and lower electrodes of the same material.

30. The method of claim 28 including forming a TiOₓ layer in said upper and lower electrodes.
